(19) United States
(12) Patent Application Publication
(10) Pub. No.: US 2019/0139821 A1
(43) Pub. Date: May 9, 2019

(54) ADVANCED BEOL INTERCONNECT ARCHITECTURE

(71) Applicant: International Business Machines Corporation, Armonk, NY (US)

(72) Inventors: Chih-Chao Yang, Glenmont, NY (US); Theo Standaert, Clifton Park, NY (US)

(21) Appl. No.: 15/807,225

(22) Filed: Nov. 8, 2017

(51) Int. Cl. H01L 21/768; H01L 23/532; H01L 21/3213

(52) U.S. Cl. CPC H01L 21/76807; H01L 21/76843; H01L 21/76879; H01L 21/3212; H01L 23/53238; H01L 21/32137; H01L 23/53223

(57) ABSTRACT

Advanced dual damascene interconnects that exhibit controlled via resistance and, in some instances, controlled line resistance are provided. In one embodiment, the structure includes an interconnect level having a combined via/line opening located therein. A diffusion barrier liner is located in at least the via portion of the combined via/line opening. A first metallic structure composed of an electrically conductive metal or metal alloy having a first bulk resistivity is located in at least the via portion of the combined via/line opening. A second metallic structure composed of an electrically conductive metal or metal alloy that has a second bulk resistivity that is higher than the first bulk resistivity is located in at least the line portion of the combined via/line opening. In accordance with the present application, second metallic structure is in direct contact with the first metallic structure.

### BACKGROUND

The present application relates to back-end-of-the-line (BEOL) semiconductor technology. More particularly, the present application relates to BEOL interconnect structures that exhibit controlled via resistance and, in some instances, controlled line resistance and methods of forming the same.

Generally, semiconductor devices include a plurality of circuits which form an integrated circuit fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring, i.e., interconnect, structures.

Within typical dual damascene interconnect structures, electrically conductive metal vias run perpendicular to the semiconductor substrate and electrically conductive metal lines run parallel to the semiconductor substrate. Typically, the electrically conductive metal vias are present beneath the electrically conductive metal lines and both features are embedded within an interconnect dielectric material layer.

In conventional dual damascene interconnect structures, copper or a copper containing alloy has been used as the material of the electrically conductive metal vias and lines. In recent years, advanced dual damascene interconnect structures containing a combined electrically conductive via/line feature have been developed in which an alternative metal such as cobalt or ruthenium has been used instead of copper or a copper alloy in the electrically conductive via only, or in both the electrically conductive via and electrically conductive line. While the use of such alternative metals in the via can provide enhanced electromigration resistance, such advanced dual damascene structures exhibit a significant via resistance increase.

There is thus a need for providing advanced dual damascene interconnect structures in which an electrically conductive via has a controlled via resistance, and, in some instances, an electrically conductive line that also has a controlled metal line resistance.

### SUMMARY

The present application provides semiconductor structures i.e., BEOL structures, that exhibit controlled via resistance and, in some instances, controlled line resistance. In one embodiment, the semiconductor structure includes an interconnect level having a combined via/line opening located therein. A diffusion barrier liner is located in at least the via portion of the combined via/line opening. A first metallic structure composed of an electrically conductive metal or metal alloy having a first bulk resistivity is located in at least the via portion of the combined via/line opening. A second metallic structure composed of an electrically conductive metal or metal alloy that has a second bulk resistivity that is higher than the first bulk resistivity is located in at least the line portion of the combined via/line opening. In accordance with the present application, the second metallic structure is in direct contact with the first metallic structure.

In another embodiment, the semiconductor structure includes an interconnect level including an interconnect dielectric material layer having a combined via/line opening located therein. A diffusion barrier liner is located in the combined via/line opening. A first metallic structure composed of a first electrically conductive metal or metal alloy is located in at least the via portion of the combined via/line opening, and a second metallic structure composed of a second electrically conductive metal or metal alloy is located in at least the line portion of the combined via/line opening. In accordance with this embodiment, a metallic seed layer separates the first metallic structure from the second metallic structure.

Another aspect of the present application relates to a method of forming such semiconductor structures. In one embodiment, the method may include providing an interconnect level comprising an interconnect dielectric material layer having a combined via/line opening located therein. Next, a diffusion barrier layer is formed in the combined via/line opening, and thereafter a first metallic seed layer is formed on the diffusion barrier layer. Next, an anneal is performed to reflow portions of the first metallic seed layer into at least the via portion of the combined via/line opening and to provide a first metallic structure located in at least the via portion of the combined via/line opening. A second metallic structure is then formed in at least the line portion of the combined via/line opening.

### BRIEF DESCRIPTION OF SEVERAL VIEWS OF THE DRAWINGS

FIG. 1 is a cross sectional view of an exemplary semiconductor structure during an early stage of fabrication and including a second interconnect dielectric material layer having a combined via/line opening formed therein and located above a lower interconnect level in accordance with an embodiment of the present application.

FIG. 2 is a cross sectional view of the exemplary semiconductor structure of FIG. 1 after forming a diffusion barrier material layer and a metallic seed layer in the combined via/line opening and on a topmost surface of the second interconnect dielectric material layer, wherein the metallic seed layer is composed of an electrically conductive metal or metal alloy having a first bulk resistivity.

FIG. 3 is a cross sectional view of the exemplary semiconductor structure of FIG. 2 after forming a first metallic structure in at least the via portion of the combined via/line opening.

FIG. 4 is a cross sectional view of the exemplary semiconductor structure of FIG. 3 after optionally removing the metallic seed layer from the line portion of the combined via/line opening.

FIG. 5 is a cross sectional view of the exemplary semiconductor structure of FIG. 4 after optionally removing the diffusion barrier material layer from the line portion of the combined via/line opening.

FIG. 6 is a cross sectional view of the exemplary semiconductor structure of FIG. 4 after forming a second metallic structure having a second bulk resistivity that is higher than the first bulk resistivity in the line portion of the combined via/line opening.

FIG. 7 is a cross sectional view of an exemplary semiconductor structure of the present application in accordance with an alternative embodiment of the present application.

FIG. 8 is a cross sectional view of an exemplary semiconductor structure of the present application in accordance with an alternative embodiment of the present application.

FIG. 9 is a cross sectional view of an exemplary semiconductor structure of the present application in accordance with an alternative embodiment of the present application.

FIG. 10 is a cross sectional view of an exemplary semiconductor structure of the present application in accordance with an alternative embodiment of the present application.

FIG. 11 is a cross sectional view of an exemplary semiconductor structure of the present application in accordance with an alternative embodiment of the present application.

FIG. 12 is a cross sectional view of an exemplary semiconductor structure of the present application in accordance with an alternative embodiment of the present application.

FIG. 13 is a cross sectional view of an exemplary semiconductor structure of the present application in accordance with an alternative embodiment of the present application.

FIG. 14 is a cross sectional view of an exemplary semiconductor structure of the present application in accordance with an alternative embodiment of the present application.

FIG. 15 is a cross sectional view of the exemplary semiconductor structure of FIG. 4 after forming a metallic seed layer in at least the line portion of the via/line opening.

FIG. 16 is a cross sectional view of the exemplary semiconductor structure of FIG. 15 after forming a second metallic structure.

FIG. 17 is a cross sectional view of an exemplary semiconductor structure of the present application in accordance with an alternative embodiment of the present application.

FIG. 18 is a cross sectional view of an exemplary semiconductor structure of the present application in accordance with an alternative embodiment of the present application.

FIG. 19 is a cross sectional view of an exemplary semiconductor structure of the present application in accordance with an alternative embodiment of the present application.

FIG. 20 is a cross sectional view of an exemplary semiconductor structure of the present application in accordance with an alternative embodiment of the present application.

FIG. 21 is a cross sectional view of an exemplary semiconductor structure of the present application in accordance with an alternative embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Advanced interconnect structures are provided that exhibit controlled via resistance and, in some embodiments, a controlled line resistance. By “controlled via resistance”, it is meant a resistance of less than 100 ohm/via. By “controlled line resistance”, it is meant a resistance of less than 1000 ohm/line. Notably, FIGS. 6-14 of the present application illustrate advanced interconnect structures of the present application that include an interconnect level, L.₊₁, including an interconnect dielectric material layer 20 having a combined via/line opening 22 located therein. A diffusion barrier liner 24L is located in at least the via portion of the combined via/line opening 22. A first metallic structure 26S composed of an electrically conductive metal or metal alloy having a first bulk resistivity is located in at least the via portion of the combined via/line opening 22. A second metallic structure 28 composed of an electrically conductive metal or metal alloy that has a second bulk resistivity that is higher than the first bulk resistivity is located in at least the line portion of the combined via/line opening 22. In accordance with the present application, second metallic structure 28 is in direct contact with the first metallic structure 26S. Bulk resistivity (or volume resistivity) is a constant value for a certain material at a certain environment (typically measured at 20° C.). The bulk resistivity is a measure of the resistivity across a defined thickness of the material.

FIGS. 16-21 of the present application illustrate advanced interconnect structures of the present application that include an interconnect level, Lₙ₊₁, including an interconnect dielectric material layer 20 having a combined via/line opening 22 located therein. A diffusion barrier liner 24L is located in the combined via/line opening 22. A first metallic structure 26S composed of a first electrically conductive metal or metal alloy is located in at least the via portion of the combined via/line opening 22, and a second metallic structure 32 composed of a second electrically conductive metal or metal alloy is located in at least the line portion of the combined via/line opening 22. In accordance with this embodiment, a metallic seed liner 30L separates the first metallic structure 26S from the second metallic structure 32.

Further details regarding the advanced interconnect structures described above are now provided.

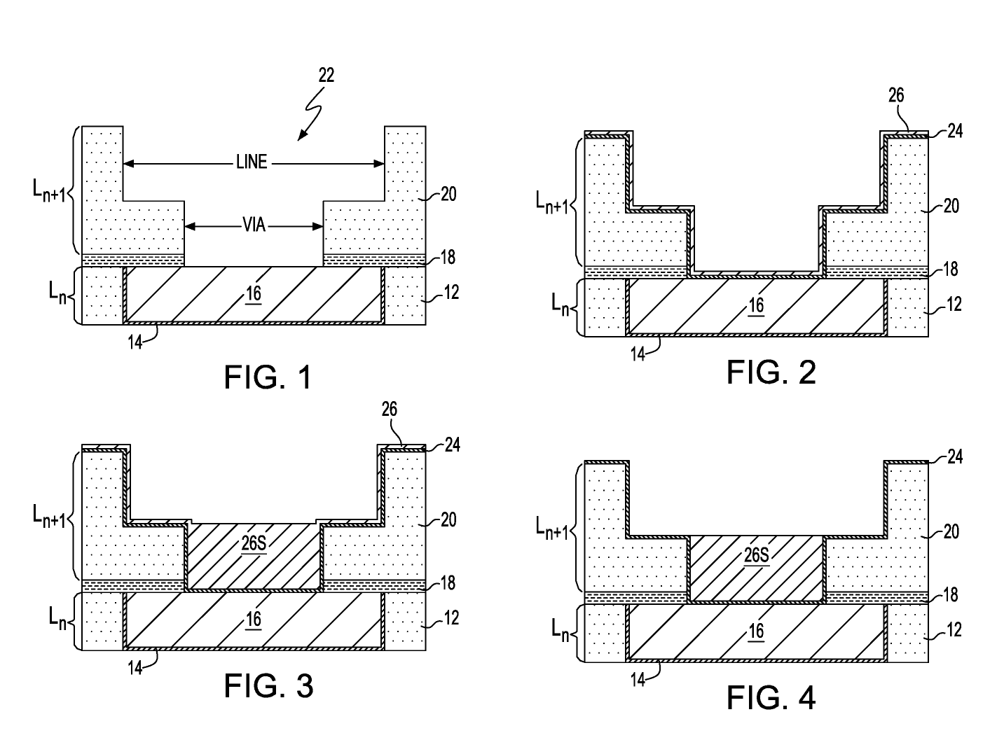

Referring first to FIG. 1, there is illustrated an exemplary semiconductor structure during an early stage of fabrication in accordance with an embodiment of the present application. As is shown, the exemplary semiconductor structure of FIG. 1 includes a second interconnect dielectric material layer 20 having a combined via/line opening 22 formed therein and located above a lower interconnect level, Lₙ. The second interconnect dielectric material layer 20 is a component of an upper interconnect level, Lₙ₊₁, wherein n is 0 or an integer starting from 1. When n is 0, the lower interconnect level, Lₙ, is omitted and replaced with a semiconductor substrate that contains a plurality of semiconductor devices formed therein or thereupon.

When present, the lower interconnect level, Lₙ, includes a first interconnect dielectric material layer 12 that includes at least one first metal-containing structure 16 embedded therein; the at least one first metal-containing structure is electrically conductive. A first diffusion barrier liner 14 is also present that surrounds the sidewalls and the bottom wall (i.e., bottommost surface) of the at least one first metal-containing structure 16 which is embedded in the first interconnect dielectric material layer 12. As is shown, the first metal-containing structure 16 and the first diffusion barrier liner 14 have topmost surfaces that are coplanar with each other as well as coplanar with a topmost surface of the first interconnect dielectric material layer 12. In some embodiments, the first diffusion barrier liner 14 may be omitted from the lower interconnect level, Lₙ. In some embodiments, the first interconnect dielectric material layer 12 may extend beneath the at least one first metal-containing structure 16 so as to completely embed the at least one first metal-containing structure 16.

The first interconnect dielectric material layer 12 of the lower interconnect level, Lₙ, may be composed of an inorganic dielectric material or an organic dielectric material. In some embodiments, first interconnect dielectric material layer 12 may be porous. In other embodiments, the first interconnect dielectric material layer 12 may be non-porous. Examples of suitable dielectric materials that may be employed as the first interconnect dielectric material layer 12 include, but are limited to, silicon dioxide, undoped or doped silicate glass, silsesquioxanes, C doped oxides (i.e., organosilicates) that include atoms of Si, C, O and H, theremosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

The first interconnect dielectric material layer 12 may have a dielectric constant (all dielectric constants mentioned herein are measured relative to a vacuum, unless otherwise stated) that is about 4.0 or less. In one embodiment, the first interconnect dielectric material layer 12 has a dielectric constant of 2.8 or less. These dielectrics generally having a lower parasitic cross talk as compared to dielectric materials whose dielectric constant is greater than 4.0.

The first interconnect dielectric material layer 12 may be formed by a deposition process such as, for example, chemical vapor deposition (CVD), plasma enhanced chemical vapor deposition (PECVD) or spin-on coating. The first interconnect dielectric material layer 12 may have a thickness from 50 nm to 250 nm. Other thicknesses that are lesser than 50 nm, and greater than 250 nm can also be employed in the present application.

After providing the first interconnect dielectric material layer 12, at least one opening (not shown) is formed into the first interconnect dielectric material layer 12; each opening will house a first metal-containing structure 16 and, if present, the first diffusion barrier liner 14. The at least one opening in the first interconnect dielectric material layer 12 may be a via opening, a line opening and/or combined a via/lines opening. The at least one opening may be formed by lithography and etching. In embodiments in which a combined via/line opening is formed, a second iteration of lithography and etching may be used to form such an opening.

In some embodiments, a first diffusion barrier material is then formed within the at least one opening and on an exposed topmost surface of the first interconnect dielectric material layer 12; the first diffusion barrier material will provide the first diffusion barrier liner 14 mentioned above. The first diffusion barrier material may include Ta, TaN, Ti, TiN, Ru, RuN, RuTa, RuTaN, W, WN or any other material that can serve as a barrier to prevent a conductive material from diffusing there through. The thickness of the first diffusion barrier material may vary depending on the deposition process used as well as the material employed. In some embodiments, the first diffusion barrier material may have a thickness from 2 nm to 50 nm; although other thicknesses for the diffusion barrier material are contemplated and can be employed in the present application as long as the first diffusion barrier material does not entirety fill the opening. The first diffusion barrier material can be formed by a deposition process including, for example, chemical vapor deposition (CVD), plasma enhanced chemical vapor deposition (PECVD), atomic layer deposition (ALD), physical vapor deposition (PVD), sputtering, chemical solution deposition or plating.

In some embodiments, an optional plating seed layer (not specifically shown) can be formed on the surface of the first diffusion barrier material. In cases in which the conductive material to be subsequently and directly formed on the first diffusion barrier material, the optional plating seed layer is not needed. The optional plating seed layer is employed to selectively promote subsequent electroplating of a pre-selected conductive metal or metal alloy. The optional plating seed layer may be composed of Cu, a Cu alloy, Ir, an Ir alloy, Ru, a Ru alloy (e.g., TaRu alloy) or any other suitable noble metal or noble metal alloy having a low metal-plating overpotential. Typically, Cu or a Cu alloy plating seed layer is employed, when a Cu metal is to be subsequently formed within the at least one opening. The thickness of the optional plating seed layer may vary depending on the material of the optional plating seed layer as well as the technique used in forming the same. Typically, the optional plating seed layer has a thickness from 2 nm to 80 nm. The optional plating seed layer can be formed by a conventional deposition process including, for example, CVD, PECVD, ALD, or PVD.

Next, a first interconnect metal or metal alloy is formed into each opening and, if present, atop the first diffusion barrier material. The first interconnect metal or metal alloy provides the first metal-containing structure 16 of the present application. The first interconnect metal or metal alloy may be composed of copper (Cu), aluminum (Al), tungsten (W), or an alloy thereof such as, for example, a Cu—Al alloy. The first interconnect metal or metal alloy can be formed utilizing a deposition process such as, for example, CVD, PECVD, sputtering, chemical solution deposition or plating. In one embodiment, a bottom-up plating process is employed in forming the first interconnect metal or metal alloy. In some embodiments, the first interconnect metal or metal alloy is formed above the topmost surface of the first interconnect dielectric material layer 12.

Following the deposition of the first interconnect metal or metal alloy, a planarization process such as, for example, chemical mechanical polishing (CMP) and/or grinding, can be used to remove all interconnect metal or metal alloy (i.e., overburden material) that is present outside each of the openings forming the first metal-containing structure 16 shown in FIG. 1. The planarization stops on a topmost surface of the first interconnect dielectric material layer 12. Thus, and if present, the planarization process also removes the first diffusion barrier material from the topmost surface of the first interconnect dielectric material layer 12. The remaining portion of the first diffusion barrier material that is present in the at least one opening is referred to herein as the first diffusion barrier liner 14, while the remaining first interconnect metal or metal alloy that is present in the at least one opening may be referred to as the first metal-containing structure 16. Collectively, the first interconnect dielectric material layer 12, each optional first diffusion barrier liner 14, and each first metal-containing structure 16 define the lower interconnect level, Lₙ, of an interconnect structure of the present application.

Next, and in some embodiments, capping layer 18 can be formed on the physically exposed topmost surface of the lower interconnect level, Lₙ, of the present application. In some embodiments, capping layer 18 can be omitted. When present, the capping layer 18 may include any dielectric material such as, for example, silicon carbide (SiC), silicon nitride (Si₃N₄), silicon dioxide (SiO₂), a carbon doped oxide, a nitrogen and hydrogen doped silicon carbide (SiC(N,H)) or a multilayered stack of at least one of the aforementioned dielectric capping materials. The capping material that provides the capping layer 18 may be formed utilizing a deposition process such as, for example, CVD, PECVD, ALD, chemical solution deposition or evaporation. When present, capping layer 18 may have a thickness from 10 nm to 100 nm. Other thicknesses that are lesser than 10 nm, or greater than 100 nm may also be used as the thickness of the capping layer 18.

Next, the second interconnect dielectric material layer 20 (without the combined via/line opening) is formed above the lower interconnect level, Lₙ. The second interconnect dielectric material layer 20 may include one of the interconnect dielectric materials mentioned above for the first interconnect dielectric material layer 12. In some embodiments, the second interconnect dielectric material layer 20 includes a same interconnect dielectric material as the first interconnect dielectric material layer 12. In other embodiments, the second interconnect dielectric material layer 20 includes a different interconnect dielectric material than the first interconnect dielectric layer 12. The second interconnect dielectric material layer 20 may be porous or non-porous, have a thickness within the thickness range of the first interconnect dielectric material layer 12, and be formed utilizing one of the deposition processes used in providing the first interconnect dielectric material layer 12.

Next, a combined via/line opening 22 (opening 22 can also be referred to herein as a dual damascene opening) can then be formed into the second interconnect dielectric material layer 20. During or, after, the formation of the via portion of the combined via opening 22, the capping layer 18 can be opened as is shown in FIG. 1 to expose a portion of the topmost surface of the at least one first metal-containing structure 16. In embodiments in which n is 0, the via portion of the combined via/line opening 22 can physically expose a conductive material or conductive region of one of the semiconductor devices that is formed upon or within a semiconductor substrate. The combined via/line opening 22 is formed utilizing a dual damascene process as known in the art. As is shown in FIG. 1, the line portion of the combined via/line opening 22 is located above the via portion of the combined via/line opening 22.

Referring now to FIG. 2, there is illustrated the exemplary semiconductor structure of FIG. 1 after forming a diffusion barrier material layer 24 and a metallic seed layer 26 in the combined via/line opening 22 and on a topmost surface of the second interconnect dielectric material layer 20.

The diffusion barrier material layer 24 includes a second diffusion barrier material which may include one of the diffusion barrier materials mentioned above for the first diffusion barrier material. In one embodiment, the first and second diffusion barrier materials may be composed of a same diffusion barrier material. In another embodiment, the first and second diffusion barrier materials are composed of different diffusion barrier materials. The second diffusion barrier material that provides diffusion barrier material layer 24 may be formed utilizing one of the deposition processes mentioned above for forming the first diffusion barrier material, and the second diffusion barrier material that provides diffusion barrier material layer 24 may have a thickness within the thickness range mentioned above for the first diffusion barrier material.

Next, the metallic seed layer 26 is formed on the diffusion barrier material layer 24. The metallic seed layer 26 that is employed in the present application is composed of an electrically conductive metal or metal alloy having a first bulk resistivity. The first bulk resistivity is typically within a range from 1.5 μΩ·cm to 3.0 μΩ·cm, wherein μΩ equals microohms. The electrically conductive metal or metal alloy that provides the metallic seed layer 26 may include copper (Cu), aluminum (Al), or a copper-aluminum (Cu—Al) alloy in which the content of copper may be greater than, equal to, or less than the content of aluminum.

The thickness of the metallic seed layer 26 may vary depending on the material of the metallic seed layer 26 as well as the technique used in forming the same. Typically, the metallic seed layer 26 has a thickness from 1 nm to 80 nm. The metallic seed layer 26 can be formed by a conventional deposition process including, for example, CVD, PECVD, ALD, or PVD.

At this stage of the present application, the diffusion barrier material layer 24 and the metallic seed layer 26 are both continuously present in the combined via/line opening 22, and a portion of the bottommost surface of the diffusion barrier material layer 24 is formed directly upon the exposed topmost surface of the a first metal-containing structure 16 of the lower interconnect level, Lₙ. Also, the diffusion barrier material layer 24 and the metallic seed layer 26 have a combined thickness that does not entirely fill the combined via/line opening 22 that is present in the second interconnect dielectric material layer 20.

Referring now to FIG. 3, there is illustrated the exemplary semiconductor structure of FIG. 2 after forming a first metallic structure 26S. In the embodiment illustrated in FIG. 3, the first metallic structure 26S completely fills in a remaining volume of the combined via/line opening 22. In the illustrated embodiment, the first metallic structure 26S has a topmost surface that does not extend beyond the topmost surface of the via portion of the combined via/line opening 22. In some embodiments the first metallic structure 26S partially fills the via portion of the combined via/line opening 22, while in other embodiments, the first metallic structure 26S may be present in the via portion as well as the line portion of the combined via/line opening 22.

The first metallic structure 26S is formed by performing a reflow anneal on the exemplary structure shown in FIG. 2. The reflow anneal may include a furnace anneal or a laser anneal; laser annealing is typically performed for a shorter period of time than furnace anneal. The reflow anneal is performed at a temperature that melts the conductive metal or metal alloy that provides the metallic seed layer 26 such that the same flows into and fills the via portion of the combined via/line opening 22 and provides the first metallic structure 26S; the first metallic structure 26S and the metallic seed layer 26 are thus composed of a same electrically conductive metal or metal alloy having the first bulk resistivity. As is known to those skilled in the art, capillary force/surface tension is the driving force pulling the metallic seed layer into the via portion of the combined via/line opening 22. Portions of the metallic seed layer 26 may remain on the sidewalls of the line portion of the combined via/line opening 22 and atop the second interconnect dielectric material 20 as shown, for example, in FIG. 3.

In some embodiments, the first metallic structure 26S can be formed as described above and thereafter a recess etching process may be performed. In such an embodiment, the first metallic structure 28S may have a topmost surface that is located beneath the topmost surface of the via portion of the combined via/line opening 22. In other embodiments, the first metallic structure 26S may partially fill in a lower portion of the line portion of the combined via/line opening 22.

Referring now to FIG. 4, there is illustrated the exemplary semiconductor structure of FIG. 3 after optionally removing the remaining metallic seed layer 26 from the line portion of the combined via/line opening 22. In some embodiments, this step of the present application can be omitted. In such an embodiment, the remaining metallic seed layer 26 in that is present in the line portion of the combined via/line opening 22 forms an upper segment of the first metallic structure 22S.

In the embodiment illustrated in FIG. 4, the entirety of the remaining metallic seed layer 26 is removed from the line portion of the combined via/line opening 22. In some embodiments, in which the first metallic structure 26S is partially present in the via portion of the combined via/line opening 22, this step may be used to remove the remaining metallic seed layer from an upper portion of the via portion of the combined via/line opening 22.

The removal of the remaining metallic seed layer 26 from the line portion of the combined via/line opening 22 may be performed utilizing a wet etch process in which a chemical etchant that is selective for removing the electrically conductive metal or metal alloy that provides the metallic seed layer 26 is employed. In one example, a mixture of metal hydroxides with other compounds can be used as the etchant. The diffusion barrier material layer 24 can be employed in the present application as an etch stop layer.

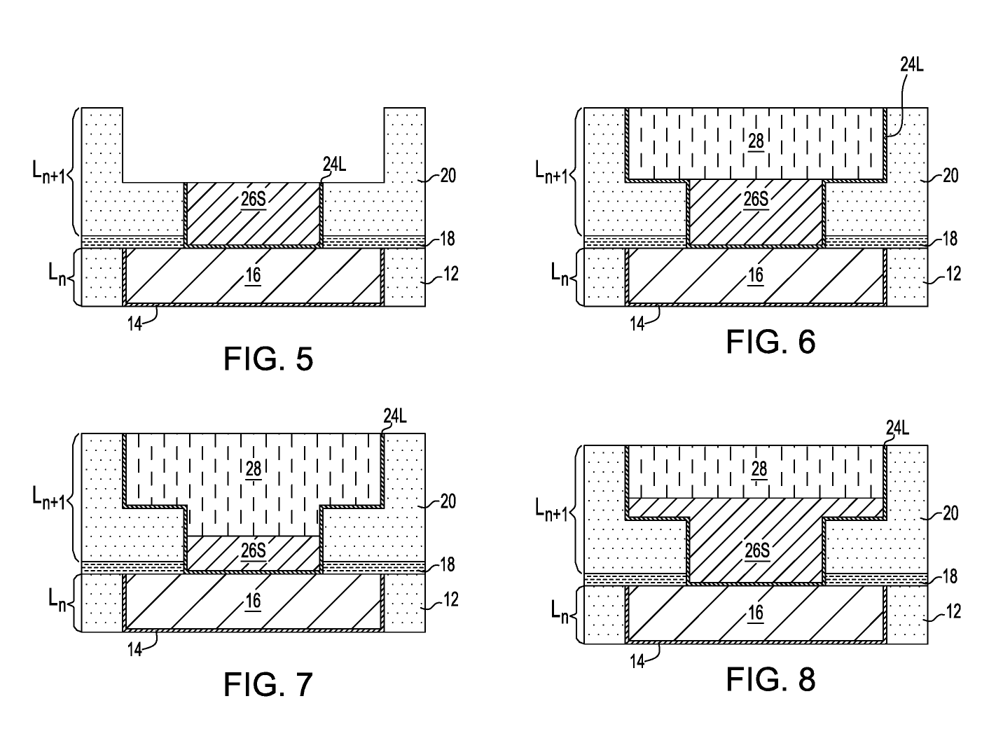

Referring now to FIG. 5, there is illustrated the exemplary semiconductor structure of FIG. 4 after optionally removing the diffusion barrier material layer 24 from the line portion of the combined via/line opening 22. In some embodiments, this step of the present application may be omitted. The portion of the diffusion barrier material layer 24 that remains in the combined via/line opening 22 is referred to herein as a diffusion barrier liner 24L. The diffusion barrier liner 24L may or may not have a topmost surface that is coplanar with a topmost surface of the first metallic structure 28S. The diffusion barrier liner 24L is present at least within the via portion of the combined via/line opening 22.

In the embodiment illustrated in FIG. 5, the entirety of the diffusion barrier material layer 24 is removed from the line portion of the combined via/line opening 22. In some embodiments, a portion of the diffusion barrier material layer 24 may remain in the line portion of the combined via/line opening 22. In other embodiments, the entirety of the diffusion barrier material layer 24 is removed from the line portion of the combined via/line opening 22 and a portion of the diffusion barrier material layer 24 can be removed from the via portion of the combined via/line opening 22.

The removal of the diffusion barrier material layer 24 from the combined via/line opening 22 may be performed utilizing a wet etch process in which a chemical etchant that is selective for removing the electrically diffusion barrier material that provides the diffusion barrier material layer 24 as compared to the electrically conductive metal or metal alloy that provides the first metallic structure 26S and the interconnect dielectric material that provides the second interconnect dielectric layer 20. For example, a mixture of compounds consisting of peroxy, azole, triazole and hydroxides can be used as the etchant. In some embodiments of the wet etch process, the first metallic structure 26S is employed as an etch mask.

Referring now to FIG. 6, there is illustrated the exemplary semiconductor structure of FIG. 4 after forming a second metallic structure 28 having a second bulk resistivity that is higher than the first bulk resistivity in the line portion of the combined via/line opening 22. The second bulk resistivity is typically within a range from to 3.5 μΩ·cm to 8.0 μΩ·cm.

The second metallic structure 28 having the second bulk resistivity that is higher than the first bulk resistivity is composed of an electrically conductive metal or metal alloy that differs from the electrically conductive metal or metal alloy that provides the metallic seed layer 26 and the first metallic structure 26S. Examples of electrically conductive metals or metal alloys that can be used in providing the second metallic structure 28 include, but are not limited to, cobalt (Co), ruthenium (Ru), rhodium (Rh), iridium (Ir), tungsten (W), nickel (Ni) or alloys thereof.

In one embodiment of the present application, the second metallic structure 28 can be formed utilizing a plating process. Electroplating or electroless plating can both be employed. The plating process deposits the electrically conductive metal or metal alloy that provides the second metallic structure 28 in upwards manner.

In some embodiments, the second metallic structure 28 can be formed by first depositing a layer of the conductive metal or metal alloy that provides the second metallic structure 28 by CVD, ALD or PVD, and thereafter performing a reflow anneal. The reflow anneal may include a furnace anneal or a laser anneal; laser annealing is typically performed for a shorter period of time than furnace anneal. The reflow anneal is performed at a temperature that melts the conductive metal or metal alloy that provides the second metallic structure 28.

In some embodiments, the second metallic structure 28 can be formed utilizing one of the above mentioned deposition processes and then a material removal process as, for example, chemical mechanical polishing, may be performed to provide a second metallic structure 28 having a topmost surface that is coplanar with at least the topmost surface of at least the second interconnect dielectric material layer 20. The second metallic structure 28 has a bottommost surface that directly contacts a topmost surface of the first metallic structure 26S.

FIG. 6 represents one exemplary semiconductor structure of the present application. In this embodiment, the exemplary semiconductor structure includes a lower interconnect level, Lₙ, that has at least one first metal-containing structure 16 embedded in a first interconnect dielectric material layer 12. An upper interconnect level, Lₙ₊₁, is present above the lower interconnect level, Lₙ. The upper interconnect level, Lₙ₊₁, includes a first metallic structure 26S and a second metallic structure 28 that are embedded in a second interconnect dielectric material layer 20. In this embodiment, the first metallic structure 26S is present only in the via portion of the combined via/line opening 22, while the second metallic structure 28 is located only within the line portion of the combined via/line opening 22. The exemplary semiconductor structure of this embodiment of the present application further includes the diffusion barrier liner 24L present in both the via portion and the line portion of the combined via/line opening 22; in this embodiment, the diffusion barrier liner 24L, and the first metallic structure 26S occupy an entirety of the via portion of the combined via/line opening 22, while the diffusion barrier liner 24L and the second metallic structure 28 occupy an entirety of the line portion of the combined via/line opening 22. In the embodiment illustrated in FIG. 6, the diffusion barrier liner 24L has topmost surfaces that are coplanar with a topmost surface of the second metallic structure 28 as well as being coplanar with a topmost surface of the second interconnect dielectric material layer 20.

FIGS. 7-14 illustrate other exemplary semiconductor structures that can be formed utilizing the basic processing steps shown in FIGS. 1-6. Notably, FIG. 7 illustrates another exemplary semiconductor structure of the present application which is a variation of the exemplary semiconductor structure shown in FIG. 6. In this embodiment and as shown in FIG. 7, the exemplary semiconductor structure includes a lower interconnect level, Lₙ, that has at least one first metal-containing structure 16 embedded in a first interconnect dielectric material layer 12. An upper interconnect level, Lₙ₊₁, is present above the lower interconnect level, Lₙ. The upper interconnect level, Lₙ₊₁, includes a first metallic structure 26S and a second metallic structure 28 that are embedded in a second interconnect dielectric material layer 20. In this embodiment, the first metallic structure 26S is present in a lower portion of the via portion of the combined via/line opening 22, while the second metallic structure 28 is located within an upper portion of the via portion as well as the line portion of the combined via/line opening 22. The exemplary semiconductor structure of this embodiment of the present application further includes the diffusion barrier liner 24L present in both the via portion and the line portion of the combined via/line opening 22; in this embodiment, the diffusion barrier liner 24L, and the first metallic structure 26S occupy a lower portion of the via portion of the combined via/line opening 22, while the diffusion barrier liner 24L and the second metallic structure 28 occupy an upper portion of the via portion of the combined via/line opening 22 and an entirety of the line portion of the combined via/line opening 22. In the embodiment illustrated in FIG. 7, the diffusion barrier liner 24L has topmost surfaces that are coplanar with a topmost surface of the second metallic structure 28 as well as being coplanar with a topmost surface of the second interconnect dielectric material layer 20.

FIG. 8 illustrates another exemplary semiconductor structure of the present application which is a variation of the exemplary semiconductor structure shown in FIG. 6. In this embodiment and as shown in FIG. 8, the exemplary semiconductor structure includes a lower interconnect level, Lₙ, that has at least one first metal-containing structure 16 embedded in a first interconnect dielectric material layer 12. An upper interconnect level, Lₙ₊₁, is present above the lower interconnect level, Lₙ. The upper interconnect level, Lₙ₊₁, includes a first metallic structure 26S and a second metallic structure 28 that are embedded in a second interconnect dielectric material layer 20. In this embodiment, the first metallic structure 26S is present in the entirety of the via portion of the combined via/line opening 22 as well as in a lower portion of the line portion of the combined via/line opening 22, while the second metallic structure 28 is located within an upper portion of the line portion of the combined via/line opening 22. The exemplary semiconductor structure of this embodiment of the present application further includes the diffusion barrier liner 24L present in both the via portion and the line portion of the combined via/line opening 22; in this embodiment, the diffusion barrier liner 24L, and the first metallic structure 26S occupy an entirety of the via portion of the combined via/line opening 22 and a lower portion of the line portion of the combined via/line opening 22, while the diffusion barrier liner 24L and the second metallic structure 28 occupy an upper portion the line portion of the combined via/line opening 22. In the embodiment illustrated in FIG. 8, the diffusion barrier liner 24L has topmost surfaces that are coplanar with a topmost surface of the second metallic structure 28 as well as being coplanar with a topmost surface of the second interconnect dielectric material layer 20.

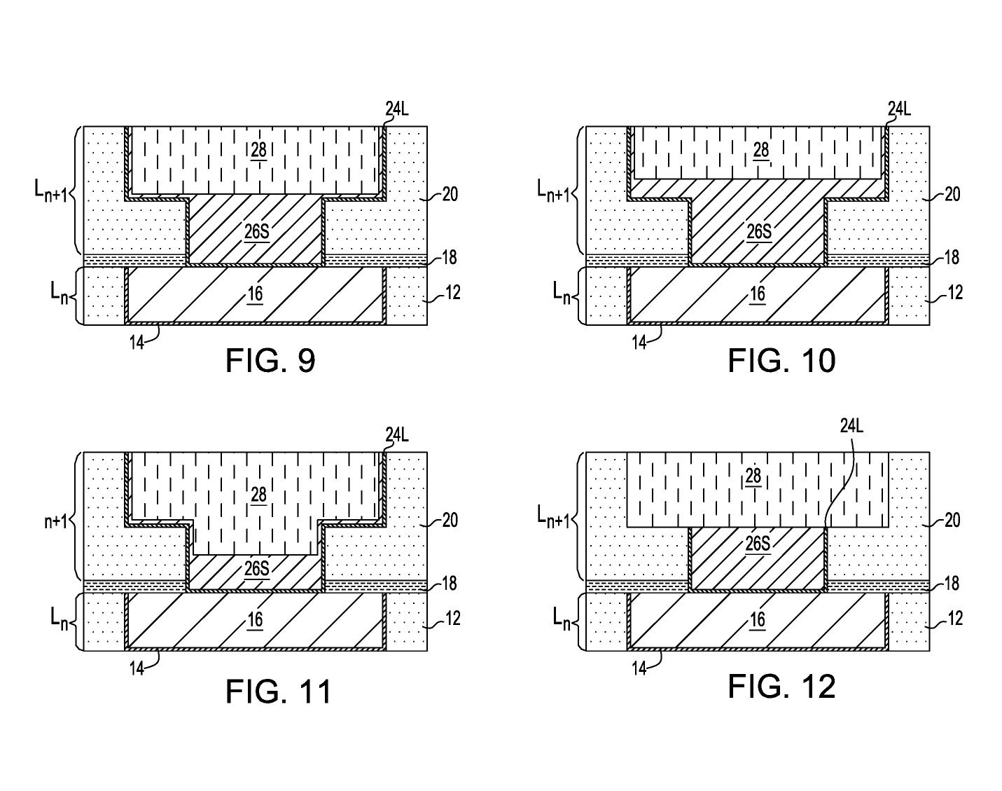

FIGS. 9-11 illustrate other exemplary semiconductor structures of the present application which are variations of the exemplary semiconductor structure shown in FIG. 6; in this embodiment the metallic seed layer 26 is not removed from the line portion of the combined via/line opening and forms an upper segment of the first metallic structure 26S that laterally surrounds the second metallic structure 28. In these embodiment and as shown in FIGS. 9-11, the exemplary semiconductor structures include a lower interconnect level, Lₙ, that has at least one first metal-containing structure 16 embedded in a first interconnect dielectric material layer 12. An upper interconnect level, Lₙ₊₁, is present above the lower interconnect level, Lₙ. The upper interconnect level, Lₙ₊₁, includes a first metallic structure 26S and a second metallic structure 28 that are embedded in a second interconnect dielectric material layer 20. In FIGS. 9-11, the first metallic structure 26S is present in the entirety of the via portion of the combined via/line opening 22 as well laterally surrounding the second metallic structure 28 that is present in the line portion of the combined via/line opening 22. The semiconductor structures of this embodiment of the present application, as shown in FIGS. 9-11, further includes the diffusion barrier liner 24L present in both the via portion and the line portion of the combined via/line opening 22; in this embodiment, the diffusion barrier liner 24L, and the first metallic structure 26S occupy an entirety of the via portion of the combined via/line opening 22, while the diffusion barrier liner 24L, an upper segment of the first metallic structure 26S and the second metallic structure 28 occupy the line portion of the combined via/line opening 22. In the embodiment illustrated in FIGS. 9-11, the diffusion barrier liner 24L and the upper segment of the first metallic structure 26S have topmost surfaces that are coplanar with a topmost surface of the second metallic structure 28 as well as being coplanar with a topmost surface of the second interconnect dielectric material layer 20.

FIGS. 12-14 illustrates other exemplary semiconductor structures of the present application which are variations of the exemplary semiconductor structure shown in FIG. 6; in these embodiments no diffusion barrier liner 24L is present between the second metallic structure 28 and the second interconnect dielectric material layer 20. In these embodiments and as shown in FIGS. 12-14, the exemplary semiconductor structures include a lower interconnect level, Lₙ, that has at least one first metal-containing structure 16 embedded in a first interconnect dielectric material layer 12. An upper interconnect level, Lₙ₊₁, is present above the lower interconnect level, Lₙ. The upper interconnect level, Lₙ₊₁, includes a first metallic structure 26S and a second metallic structure 28 that are embedded in a second interconnect dielectric material layer 20. In each of FIGS. 12-14, the diffusion barrier liner 24L has topmost surfaces that are coplanar with a topmost surface of the first metallic structure 26S, while the second metallic structure 28 has a topmost surface that is located above the topmost surface of the first metallic structure 26S and is coplanar with a topmost surface of the second interconnect dielectric material layer 20.

In the embodiment illustrated in FIG. 12, the first metallic structure 26S is present in the entirety of the via portion of the combined via/line opening 22, while the second metallic structure 28 is present in the entirety of the line portion of the combined via/line opening 22. In FIG. 12, the diffusion barrier liner 24L is only present in the via portion of the combined via/line opening 22.

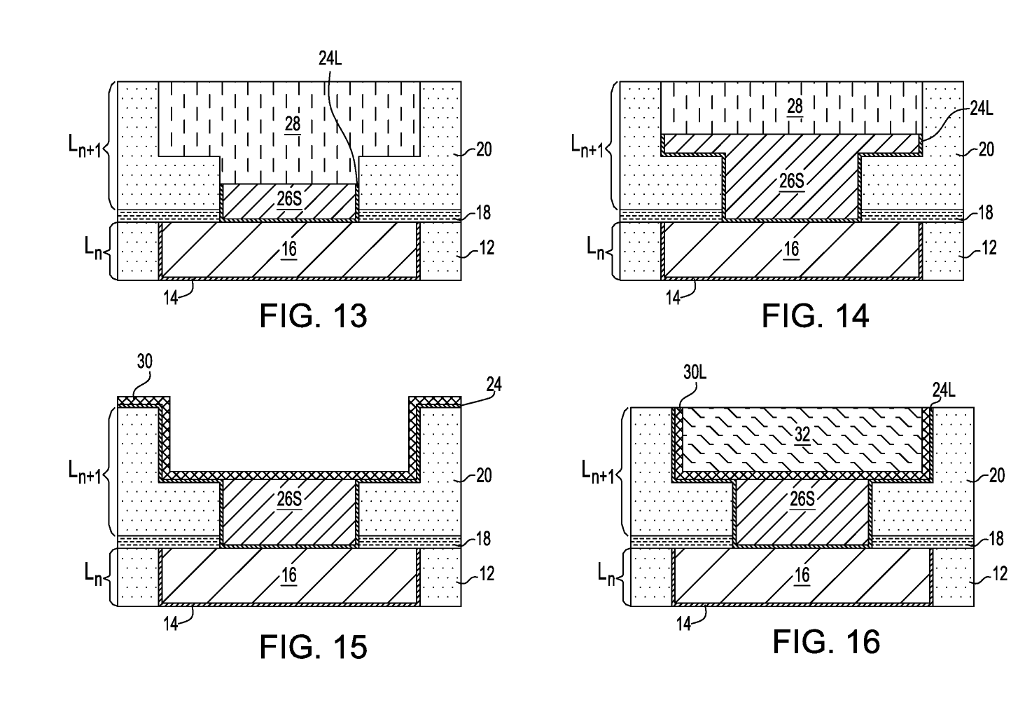

FIG. 13 illustrates an embodiment in which the first metallic structure 26S is present in a lower portion of the combined via/line opening 22, while the second metallic structure 28 is present in an upper portion of the via portion of the combined via/line opening 22 as well as the entirety of the line portion of the combined via/line opening 22. In FIG. 13, the diffusion barrier liner 24L is only present in the lower portion of via portion of the combined via/line opening 22.

FIG. 14 illustrates an embodiment in which the first metallic structure 26S is present in the entirety of the via portion of the combined via/line opening 22 as well as a lower portion of the line portion of the combined via/line opening 22, while the second metallic structure 28 is present in an upper portion of the line portion of the combined via/line opening 22. In FIG. 14, the diffusion barrier liner 24L is present in the entirety of the via portion as well as a lower portion of line portion of the combined via/line opening 22.

The exemplary semiconductor structure of this embodiment of the present application further includes the diffusion barrier liner 24L present in both the via portion and the line portion of the combined via/line opening 22; in this embodiment, the diffusion barrier liner 24L, and the first metallic structure 26S occupy an entirety of the via portion of the combined via/line opening 22, while the diffusion barrier liner 24L, an upper segment of the first metallic structure 26S and the second metallic structure 28 occupy the line portion of the combined via/line opening 22. In the embodiment illustrated in FIG. 14, the diffusion barrier liner 24L and the first metallic structure 26S have topmost surfaces that are coplanar with each other. In this embodiment, the diffusion barrier liner 24L is located entirely beneath the second metallic structure 28.

Referring now to FIG. 15, there is illustrated the exemplary semiconductor structure of FIG. 4 after forming a metallic seed layer 30 in at least the line portion of the via/line opening.

The metallic seed layer 30 of this embodiment of the present application is formed on the diffusion barrier material layer 24 as well as on the first metallic structure 26S. In some embodiments, the metallic seed layer 30 that is employed in the present application is composed of an electrically conductive metal or metal alloy that is the same as the electrically conductive metal or metal alloy that is used in providing the second metallic structure 32. In some embodiments, the metallic seed layer is composed of an electrically conductive metal or metal alloy that differs from the second metallic structure 32. The metallic seed layer 30 may comprise a same, or different electrically conductive metal or metal alloy as the first metallic structure 26S. In this embodiment, the electrically conductive metal or metal alloy that provides the first metallic structure 26S may be referred to as a first electrically conductive metal or metal alloy.

In some embodiments, the electrically conductive metal or metal alloy that provides the metallic seed layer 30 may have a first bulk resistivity which is typically within a range from 1.5 μΩ·cm to 3.0 μΩ·cm, wherein μΩ equals microohms. Examples of such electrically conductive metals or metal alloys include, but are not limited to, copper (Cu), aluminum (Al), or a copper-aluminum (Cu—Al) alloy in which the content of copper may be greater than, equal to, or less than the content of aluminum.

In some embodiments, the electrically conductive metal or metal alloy that provides the metallic seed layer 30 may have a second bulk resistivity higher than the first bulk resistivity of the metallic seed layer 26 used in providing the first metallic structure. The second bulk resistivity is typically within a range from to 3.5 μΩ·cm to 8.0 μΩ·cm. Examples of such electrically conductive metals or metal alloys that can be used in providing the metallic seed layer 3—include, but are not limited to, cobalt (Co), ruthenium (Ru), rhodium (Rh), iridium (Ir), tungsten (W), nickel (Ni) or alloys thereof.

The thickness of the metallic seed layer 30 may vary depending on the material of the metallic seed layer 30 as well as the technique used in forming the same. Typically, the metallic seed layer 30 has a thickness from 1 nm to 80 nm. The metallic seed layer 30 can be formed by a conventional deposition process including, for example, CVD, PECVD, ALD, or PVD. At this stage of the present application, the diffusion barrier material layer 24 and the metallic seed layer 26 are both continuously present in the line portion of the combined via/line opening 22.

Referring now to FIG. 16, there is illustrated the exemplary semiconductor structure of FIG. 15 after forming a second metallic structure 32. The second metallic structure 32 is composed of a second electrically conductive metal or metal alloy, which may be the same as, or different from, the electrically conductive metal or metal alloy that provides the metallic seed layer 30. Stated in other terms, the second metallic structure has a second bulk resistivity that is equal to or higher than the first bulk resistivity of the first metallic structure. In some embodiments, the second metallic structure 32 may be composed of a second electrically conductive metal or metal alloy having the first bulk resistivity mentioned above. Examples of such electrically conductive metals or metal alloys include, but are not limited to, copper (Cu), aluminum (Al), or a copper-aluminum (Cu—Al) alloy in which the content of copper may be greater than, equal to, or less than the content of aluminum.

In other embodiments, the second metallic structure 32 may be composed of a second electrically conductive metal or metal alloy having the second bulk resistivity mentioned above. Examples of such electrically conductive metals or metal alloys include, but are not limited to, cobalt (Co), ruthenium (Ru), rhodium (Rh), iridium (Ir), tungsten (W), nickel (Ni) or alloys thereof.

The second metallic structure 28 is formed by first depositing one of the above mentioned second electrically conductive metal or metal alloys, and thereafter performing a planarization process. The planarization process removes any overburden material that is present outside the combined via/line opening 22 and on the topmost surface of the second interconnect dielectric material layer 20. The remaining metallic seed layer 30 that is present in the combined via/line opening is referred to herein as metallic seed liner 30L, while the remaining diffusion barrier layer 24 that is present in the combined via/line opening 22 is referred to herein as a diffusion barrier liner 24L.

FIG. 16 illustrates an embodiment of the present application that includes an interconnect level, Lₙ₊₁ comprising an interconnect dielectric material layer 20 having a combined via/line opening 22 located therein. A diffusion barrier liner 24L is located in the combined via/line opening 22. A first metallic structure 26S composed of a first electrically conductive metal or metal alloy is located in at least the via portion of the combined via/line opening 22, and a second metallic structure 32 composed of a second electrically conductive metal or metal alloy is located in at least the line portion of the combined via/line opening 22. In accordance with this embodiment, a metallic seed layer 30L that is composed of a same or different electrically conductive metal or metal alloy than the second metallic structure 32 separates the first metallic structure 26S from the second metallic 32. In this embodiment, the metallic seed layer 30L is U-shaped. By “U-shaped” it is meant that a material has a horizontal portion and a vertical portion that extends upwards from each end of the horizontal portion. As is shown in FIG. 16, the metallic seed layer 30L has topmost surfaces that are coplanar with a topmost surface of the second metallic structure 32 as well as topmost surfaces of the diffusion barrier liner 24L and the second interconnect dielectric material layer 20. In the embodiment illustrated in FIG. 16, the first metallic structure 26S is confined to the via portion of the combined via/line opening 22, while the second metallic structure 32 is confined to the line portion of the combined via/line opening 22.

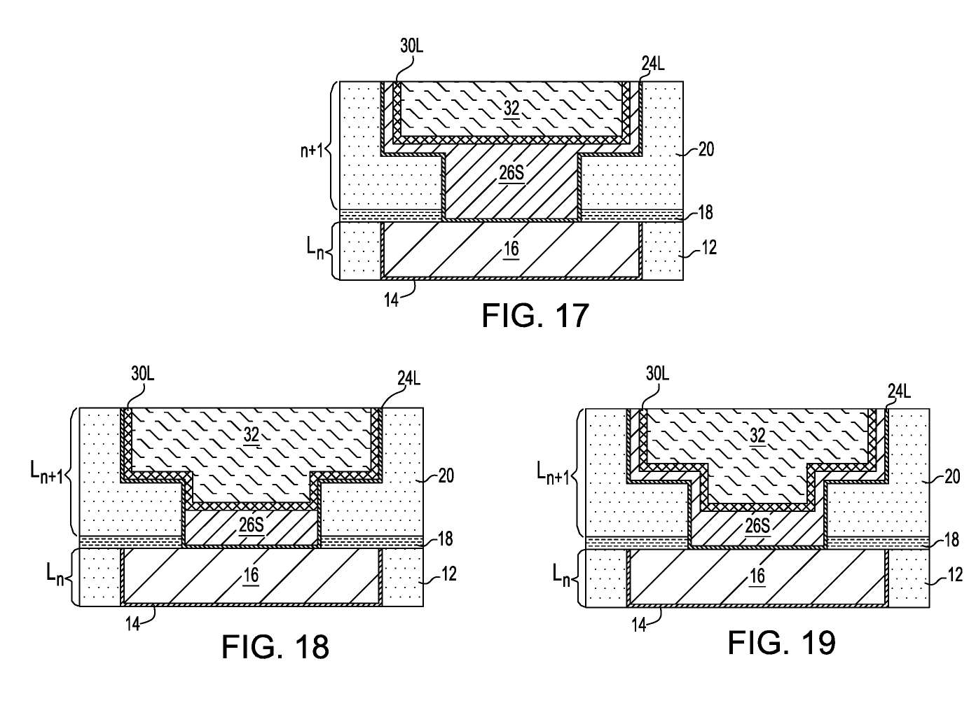

Referring now to FIGS. 17-21, there are illustrated exemplary semiconductor structures of the present application in accordance with an alternative embodiment of the present application. The exemplary structures shown in FIGS. 17-21are variations of the exemplary structure shown in FIG. 16 and such structures can be formed utilizing the various processes steps mentioned in the present application.

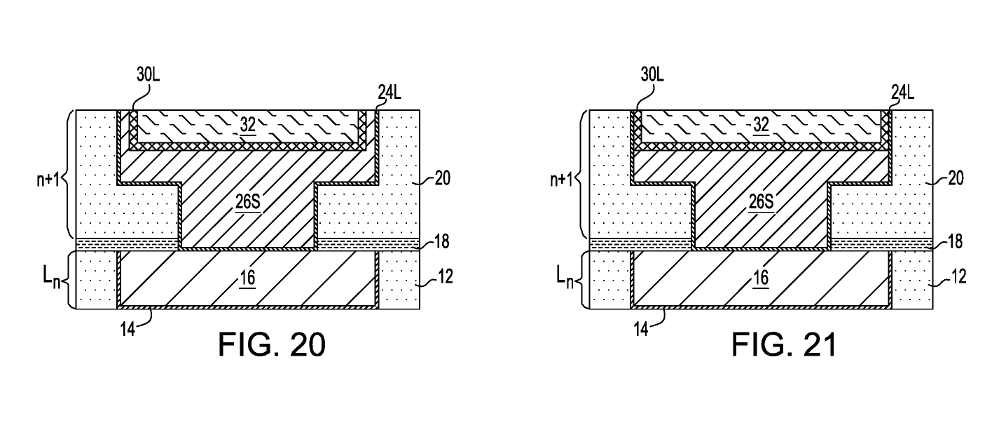

Notably, FIGS. 17, 19 and 21 illustrate structures in which the first metallic seed layer is not removed from the line portion of the combined via/line opening 22, and thus forms an upper segment of the first metallic structure 26S that is present in the line portion of the combined via/line opening 22. FIG. 18 illustrates embodiments in which the first metallic structure 26S is present only in a lower portion of the via portion of the combined via/opening 22, while FIG. 20 illustrates a structure in which the first metallic structure 26S is present in the via portion and a lower portion of the line portion of the combined via/line opening 22.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
an interconnect level comprising an interconnect dielectric material layer having a combined via/line opening located therein;
a diffusion barrier liner located in at least the via portion of the combined via/line opening;
a first metallic structure composed of an electrically conductive metal or metal alloy having a first bulk resistivity and located in at least the via portion of the combined via/line opening; and
a second metallic structure composed of an electrically conductive metal or metal alloy that has a second bulk resistivity that is higher than the first bulk resistivity and located in at least the line portion of the combined via/line opening, wherein the second metallic structure is in direct contact with the first metallic structure.

2. The semiconductor structure of claim 1, wherein the first bulk resistivity is from 1.5 μΩ·cm to 3.0 μΩ·cm, and the second bulk resistivity is from 3.5 μΩ·cm to 8.0 μΩ·cm.

3. The semiconductor structure of claim 2, wherein the electrically conductive metal or metal alloy that provides the first metallic structure comprises copper (Cu), aluminum (Al), or a copper-aluminum (Cu—Al) alloy, and the electrically conductive metal or metal alloy that provides the second metallic structure comprises cobalt (Co), ruthenium (Ru), rhodium (Rh), iridium (Ir), tungsten (W), nickel (Ni) or alloys thereof.

4. The semiconductor structure of claim 1, wherein the first metallic structure is present only in the via portion of the combined via/line opening, and the second metallic structure is present only in the line portion of the combined via/line opening.

5. The semiconductor structure of claim 1, wherein the first metallic structure is present only in a lower portion of the via portion of the combined via/line opening, and the second metallic structure is present in an upper portion of the via portion of the combined via/line opening and in the line portion of the combined via/line opening.

6. The semiconductor structure of claim 1, wherein the first metallic structure is present in the via portion of the combined via/line opening and in a lower portion of the line portion of the combined via/line opening, and the second metallic structure is present in an upper portion of the line portion of the combined via/line opening.

7. The semiconductor structure of claim 1, wherein the first metallic structure comprises an upper segment that laterally surrounds the second metallic structure.

8. A semiconductor structure comprising:
an interconnect level comprising an interconnect dielectric material layer having a combined via/line opening located therein;
a diffusion barrier liner located in the combined via/line opening;
a first metallic structure composed of a first electrically conductive metal or metal alloy and located in at least the via portion of the combined via/line opening; and
a second metallic structure composed of a second electrically conductive metal or metal alloy located in at least the line portion of the combined via/line opening, wherein a metallic seed layer separates the first metallic structure from the second metallic.

9. The semiconductor structure of claim 8, wherein the first electrically conductive metal or metal alloy has a first bulk resistivity and the second electrically conductive metal or metal alloy has a second bulk resistivity that is higher than the first bulk resistivity.

10. The semiconductor structure of claim 9, wherein the first bulk resistivity is from 1.5 μΩ·cm to 3.0 μΩ·cm, and the second bulk resistivity is from 3.5 μΩ·cm to 8.0 μΩ·cm.

11. The semiconductor structure of claim 10, wherein the first electrically conductive metal or metal alloy comprises copper (Cu), aluminum (Al), or a copper-aluminum (Cu—Al) alloy, and the second electrically conductive metal or metal alloy that provides the second metallic structure comprises cobalt (Co), ruthenium (Ru), rhodium (Rh), iridium (Ir), tungsten (W), nickel (Ni) or alloys thereof.

12. The semiconductor structure of claim 8, wherein the first electrically conductive metal or metal alloy is the same as the second electrically conductive metal or metal alloy.

13. The semiconductor structure of claim 8, wherein the first metallic structure is present only in the via portion of the combined via/line opening, and the second metallic structure is present only in the line portion of the combined via/line opening.

14. The semiconductor structure of claim 8, wherein the first metallic structure is present only in a lower portion of the via portion of the combined via/line opening, and the second metallic structure is present in an upper portion of the via portion of the combined via/line opening and in the line portion of the combined via/line opening.

15. The semiconductor structure of claim 8, wherein the first metallic structure is present in the via portion of the combined via/line opening and in a lower portion of the line portion of the combined via/line opening, and the second metallic structure is present in an upper portion of the line portion of the combined via/line opening.

16. The semiconductor structure of claim 8, wherein the first metallic structure comprises an upper segment that laterally surrounds the second metallic structure.

17. A method of forming a semiconductor structure comprising:
providing an interconnect level comprising an interconnect dielectric material layer having a combined via/line opening located therein;
forming a diffusion barrier layer in the combined via/line opening;
forming a first metallic seed layer on the diffusion barrier layer;
performing an anneal to reflow portions of the first metallic seed layer into at least the via portion of the combined via/line opening and to provide a first metallic structure located in at least the via portion of the combined via/line opening; and
forming a second metallic structure in at least the line portion of the combined via/line opening.

18. The method of claim 17, wherein the first metallic seed layer and the first metallic structure comprise a first electrically conductive metal or metal alloy having a first bulk resistivity and the second metallic structure comprises a second electrically conductive metal or metal alloy having a second bulk resistivity that is equal to or higher than the first bulk resistivity, and wherein the second metallic structure directly contacts a surface of the first metallic structure.

19. The method of claim 17, wherein, prior to forming the second metal structure, a second metallic seed layer is formed in at least the line portion of the combined via/line opening to separate the first metallic structure from the second metallic structure.

20. The method of claim 19, wherein the first metallic seed layer and the first metallic structure comprise a first electrically conductive metal or metal alloy having a first bulk resistivity and the second metallic structure comprises a second electrically conductive metal or metal alloy having a second bulk resistivity that is equal to or higher than the first bulk resistivity, and wherein the second metallic structure directly contacts a surface of the first metallic structure.
